(19) United States
(12) Patent Application Publication
(10) Pub. No.: US 2011/0290554 A1
(43) Pub. Date: Dec. 1, 2011

(54) APPARATUS FOR ADJUSTING ENVIRONMENTAL CONDITIONS FOR AN ELECTRICAL COMPONENT

(75) Inventors: Michael BOGNER, ECKENTAL (DE); Raphael FISCHER, HERZOGENAURACH (DE)

(73) Assignee: SCHAEFFLER TECHNOLOGIES GMBH & CO. KG

(21) Appl. No.: 13/118,728

(22) Filed: May 31, 2011

(30) Foreign Application Priority Data
Jun. 1, 2010 (DE) 10 2010 022 327.1

(51) Int. Cl. H05K 7/20; H05K 5/00

(52) U.S. Cl. 174/547; 174/520

(57) ABSTRACT

An apparatus for adjusting substantially constant environmental conditions for an electrical component, which conducts and/or stores current. The electrical component is surrounded by a housing, which has an opening to obtain a connection to the external environment of the housing. The housing has means, which protect the electrical component substantially from dirt, dust and/or moisture from the external environment.

### CROSS-REFERENCE TO RELATED APPLICATION

This application claims the benefit of DE 10 2010 022 327.1 filed Jun. 1, 2010, which is incorporated by reference herein.

### FIELD OF THE INVENTION

The invention relates to an apparatus for adjusting environmental conditions for an electrical component. In particular, the electrical component conducts and/or stores current. The electrical component is surrounded by a housing which has formed an opening which produces a connection to the external environment of the housing.

### BACKGROUND OF THE INVENTION

The German patent application DE 69210845 T2 describes a cover arrangement for an electrical storage battery, consisting of a cover molding which serves the purpose of closing an upper, open face of a battery box during use. In addition, the cover molding has a ventilation channel, which has an opening at the end of the end face of the molding and is connected to a large number of compartments during use. A through-bore is blocked by a porous flame arrester element. A combustion chamber is provided on the environmental air side of the flame arrester element, with the result that gases can pass through the porous flame arrester element. The insert in which the element is contained is located substantially entirely within the channel which is accommodated in the cover molding. In addition, an insert sleeve is arranged in the ventilation channel with a clamping fit, with the result that the large surface contact area between the insert sleeve and the wall of the channel has a sealing effect. Similarly, the ventilation channel is equipped with a pressure relief valve. This pressure relief valve opens when the gas pressure in the channel exceeds a predetermined value in order to remove the pressure from the channel.

### SUMMARY OF THE INVENTION

The invention is based on the object of providing an apparatus which is designed such that it protects an electrical component from influences such as dirt, moisture, dust, for example, in a simple and effective manner and provides operating conditions which are as identical as possible over time for the component.

According to the invention, the object is achieved by an apparatus adjusting substantially constant operating conditions for an electrical component, conducts and/or stores current and is surrounded by a housing that has an opening which produces a connection to the external environment of the housing. The electrical component may be a battery module or an electric drive motor. The housings for battery modules and for drive motors need to be configured with hermetic sealing in order to prevent the ingress of a flow of material and/or particles. This flow may be dirt, dust and/or moisture. In addition, there is at the same time the need for air exchange or pressure compensation. This can take place by means of an opening in at least one wall of the housing. This opening produces a connection to the external environment of the housing.

During operation of the electrical component, heat is generated. Owing to the encapsulation, the pressure in the interior of the housing is therefore increased. The at least one opening which is produced in a wall of the housing is used for pressure compensation with the environment. Over the entire use temperature range, it is necessary to ensure sufficient compensation at superatmospheric or subatmospheric pressure in comparison with the environment.

The use temperature range of the electrical components extends between −30° C. and ±120° C., depending on the component, wherein battery modules permit relatively low maximum temperatures of approximately 60° C., whereas the drive motors fluctuate within the specified range.

Furthermore, pressure compensation is necessary in motors in order to relieve the load on shaft seals. During hermetic encapsulation of motors, it is necessary for the seals, apart from the conventional sealing effect with respect to dirt and moisture, to be sealed from the outside and with respect to the emergence of lubricant from the bearing arrangements. The seals are necessary for withstanding the potential pressure difference. Likewise, the battery modules need to be kept at a constant pressure level in order to ensure the chemical stability of the cells. Secondly, the cells are located in housings consisting of sheet metal, with it being necessary for said housings to be stable in order to withstand a pressure difference.

In order to achieve the adjustments of environmental conditions or the matching of environmental conditions in the interior of the housing, means are arranged in the interior of the housing which protect the electrical component with respect to influences from the external environment.

In order to achieve efficient protection, a compensating volume is provided in accordance with the invention. In this case, the compensating volume is provided completely in the interior of the housing. In order to counteract the influences, such as moisture and dirt, for example, at least one corresponding means is provided in the interior of the housing, said means providing the compensating volume. The compensating volume is connected to the external environment of the housing by virtue of the opening.

In addition, the apparatus discloses a separation between the compensating volume and the electrical component provided in the interior of the housing. This separation is achieved by means of an elastic membrane and/or an elastic bubble. It has proven to be particularly advantageous for the compensating volume to be capable of being formed to a greater or lesser extent, depending on the pressure level in the interior of the component, owing to the elastic membrane and/or the elastic bubble. Furthermore, the elastic membrane and/or the elastic bubble represents a hermetically sealing protective sleeve for the electrical component in the interior of the housing. The electrical component is therefore completely isolated from the external environment. Despite the opening in the housing, the incoming, external environmental influences, such as dirt, dust and/or moisture, for example, do not reach the electrical component and are deterred from penetrating further into the interior of the housing by the means such as the elastic membrane and/or the elastic bubble, for example.

The apparatus according to the invention also demonstrates that a filter device is associated with the opening. In addition, a moisture-absorbing element can also be connected downstream of the filter device. A temperature difference between the interior of the housing and the external environment may prevail, which can result in condensation of moisture on the interior of the walls of the housing. In order to prevent this, a moisture-absorbing element is provided.

At low temperatures in winter, the temperature difference results in it being possible for the moisture from the air to be deposited on the inner wall of the housing. Although the moisture is prevented from advancing as far as the electrical component by virtue of the elastic membrane and/or the elastic bubble, the condensation between the membrane and the wall is not prevented. In this case, a condensate may be deposited, particularly on the boundary area of the compensating volume which is formed by the elastic membrane and the inner side of the housing wall, which consequently results in corrosion damage. In order to counteract this problem of moisture, a moisture-absorbing element is incorporated. This has the advantage of meeting the requirement for less atmospheric moisture in the interior of the housing. By virtue of the measure of incorporating a moisture-absorbing element, corrosion damage on the electrical component or on the housing is ruled out. Efficient absorption takes place by means of a superabsorber. The type of superabsorber to be used has long been known from the prior art.

By means of this arrangement, it is possible to comply with the requirements for low atmospheric moisture and air exchange in order to reduce the water content in the incoming air to such an extent that there is no condensation and, at the same time, the air flowing through is free of solid particles.

In a further variant of the apparatus according to the invention, cooling is associated with the electrical component in the interior of the housing. The electrical component is therefore protected in an advantageous manner with respect to overheating in the interior of the housing. In addition, the cooling ensures overheating-related shutdown of the electrical component and reduces the possibilities of a technical defect.

In addition, the cooling can be guided by means of a pipeline system via the moisture-absorbing element. For cooling purposes, a suitable coolant is guided in the pipeline system. The cooling for the electrical component takes place in the form of active cooling in the interior of the housing. The temperature difference is reduced by the heat exchange, with the result that the condensation in the interior of the housing is thus likewise reduced.

### BRIEF DESCRIPTION OF THE DRAWINGS

The invention and advantages thereof will be explained below with reference to the attached figures, in which:

FIG. 1 shows a first embodiment of the apparatus according to the invention, with a filter and a superabsorber being provided;

FIG. 2 shows an embodiment of the apparatus shown in FIG. 1, with cooling additionally being provided;

FIG. 3 shows an embodiment of the apparatus, with the electrical component being isolated by means of a membrane; and

FIG. 4 shows an embodiment of the apparatus shown in FIG. 3, with the compensating volume being formed by a bubble.

### DETAILED DESCRIPTION OF THE INVENTION

Identical reference symbols are used for identical or functionally identical elements of the invention. In addition, for reasons of clarity, only reference symbols which are required for describing the respective figure are represented in the individual figures. The embodiments shown merely represent examples for the possible configuration of the apparatus according to the invention. Therefore, they do not restrict the invention in any way.

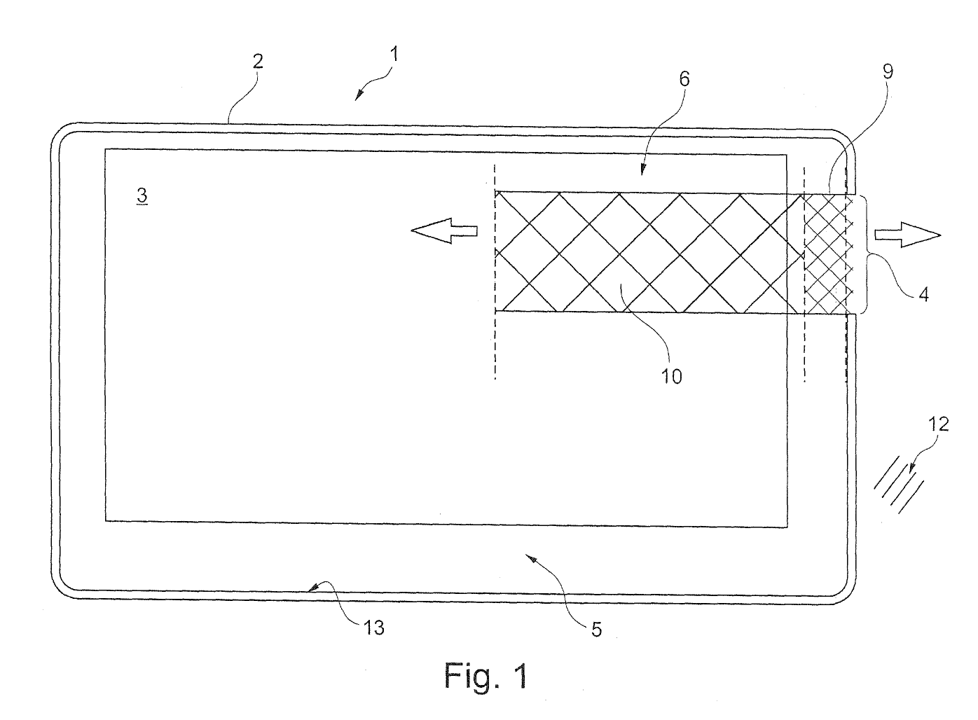

FIG. 1 shows a first exemplary embodiment of the apparatus 1 according to the invention which is surrounded by a housing 2. An electrical component 3 is arranged within the housing 2 and is surrounded thereby completely. The electrical component 3 may be a current-conducting and/or a current-storing component. A possible electrical component 3 is an electric motor or a battery module. The housing 2 has at least one opening 4, which is connected to the external environment 12 of the apparatus 1 or the housing 2. At least one means 6 is associated with the opening 4, said means protecting the electrical component 3 from influences from the external environment 12. The means 6 is at least one filter device 9. In the embodiment shown in FIG. 1, in addition at least one moisture-absorbing element 10 is connected downstream of the filter device 9. The filter device 9, which is arranged directly in the vicinity of the opening 4, is intended to provide sealing with respect to influences from the external environment 12, in order to prevent the ingress of dirt, for example. In addition, the filter device 9 is also intended to filter dust and dirt particles in order to protect the electrical component 3 from any impairment to its function.

As already mentioned, a moisture-absorbing element 10 is connected downstream of the filter device 9. The necessity for the dehumidification of incoming air by the moisture-absorbing element 10 exists as a result of the fact that a temperature difference prevails between the interior 5 of the housing 2 and the external environment 12. At low temperatures, such as in winter, for example, the temperature difference means that it is possible for the moisture to be deposited from the air on the housing inner wall 13. The condensation on the housing inner wall 13 then ultimately results in corrosion damage to the electrical component 3 and/or the housing 2. Therefore, the requirement for low atmospheric moisture, on the one hand, and air exchange, on the other hand, needs to be realized such that the water content of the incoming air is reduced to such an extent that deposition on cold housing parts is ruled out. The efficient absorption of moisture by the moisture-absorbing element 10 is performed by means of a superabsorber. Various products are possible superabsorbers. These products may be, inter alia, FAVOR® by Evonik and Luquafleece® by BASF. When considered from a chemical point of view, the superabsorber is a sodium polyacrylate. The most important property is the fact that it begins to swell on contact with liquid. For example, the superabsorber can absorb a quantity of 130 ml of water and 0 ml of ethanol of absorbing liquid given an intrinsic weight of 1 g, i.e. 130 times the quantity of its intrinsic weight in liquid.

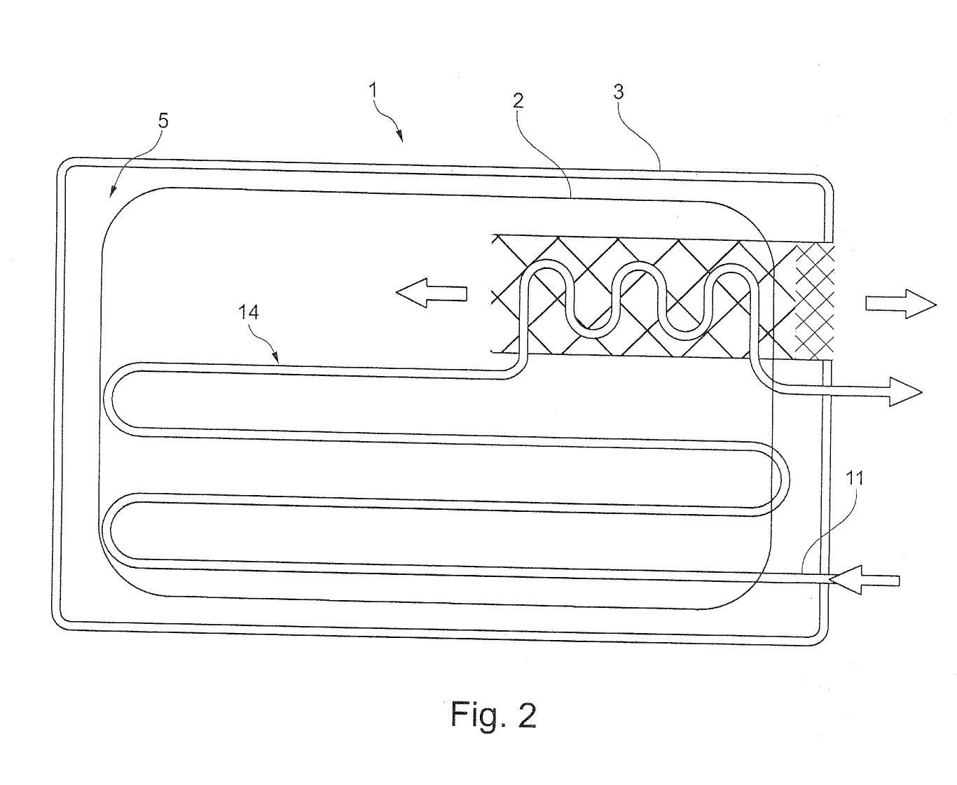

FIG. 2 shows a second exemplary embodiment of the apparatus 1 according to the invention, in which cooling 11 for the electrical component 3 is provided in the interior 5 of the housing 2. The cooling 11 for the electrical component 3 can be provided in the interior 5 of the housing 2 in the form of active cooling. For the cooling 11, a suitable coolant is guided in a pipeline system 14. In addition, the heat-dissipating pipeline 14 can be laid around or through the moisture-absorbing element 10. The advantage of active cooling consists in that the flow rate of the warm air flow is substantially greater than in the case of passive cooling. This advantage of the heat exchange reduces the temperature difference between the interior 5 of the housing 2 and the external environment 12 and reduces the condensation and therefore the susceptibility to corrosion of the electrical component 3 and/or the housing 2.

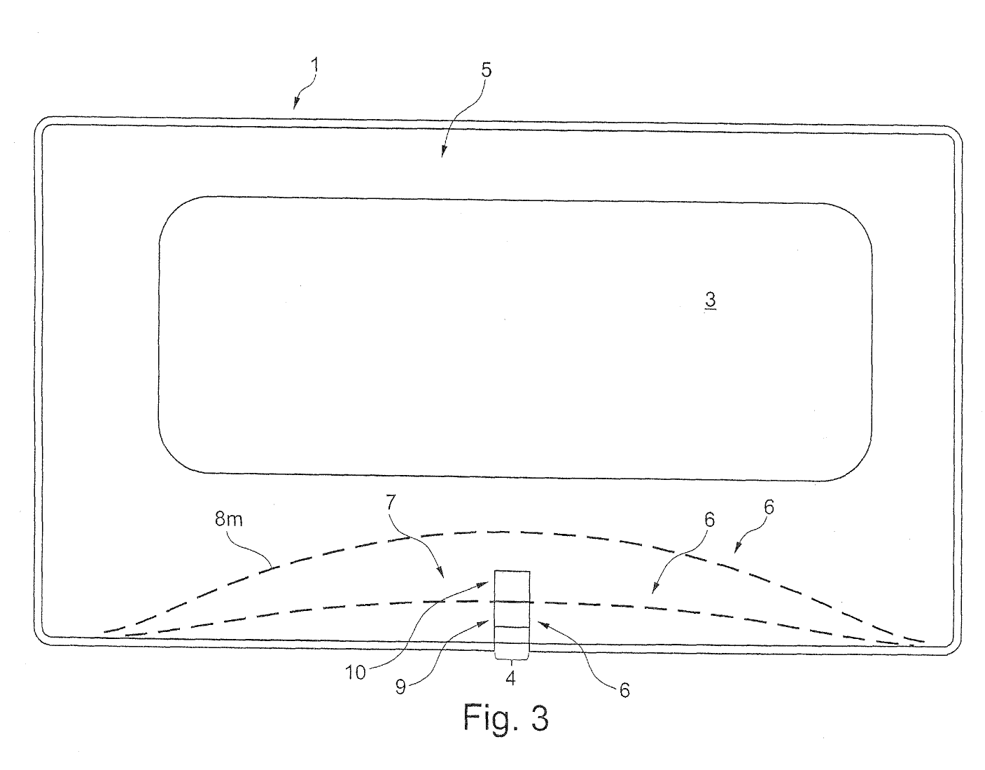

FIG. 3 shows a third exemplary embodiment of the apparatus 1 according to the invention, with the opening 4 being separated from the electrical component 3 by a means 6. The elastic membrane 8m prevents moisture and dirt from gaining access to the electrical component 3. In order to prevent the ingress of moisture between the elastic membrane 8m and the housing 2, a filter device 9 and/or a moisture-absorbing element 10 can be connected downstream of the opening 4. Provided in the interior 5 of the housing 2 and next to and/or around the electrical component 3 are the means 6 which enable hermetic lockdown of the electrical component 3 with respect to the external environment 12. These means 6 are in the form of an elastic membrane 8m and can therefore represent a compensating volume 7. The compensating volume 7 is provided for the purpose of making it possible for the elastic membrane 8m to expand to a greater or lesser extent, depending on the pressure level. The measure of a compensating volume 7 is intended to make it possible to achieve a pressure level in the interior 5 of the housing 2 which is as constant as possible in order to ensure chemical stability of the cells for the battery modules. Secondly, the pressure compensation is necessary for motors in order to relieve seals of load without obtaining an increased frictional torque in the seals in the process.

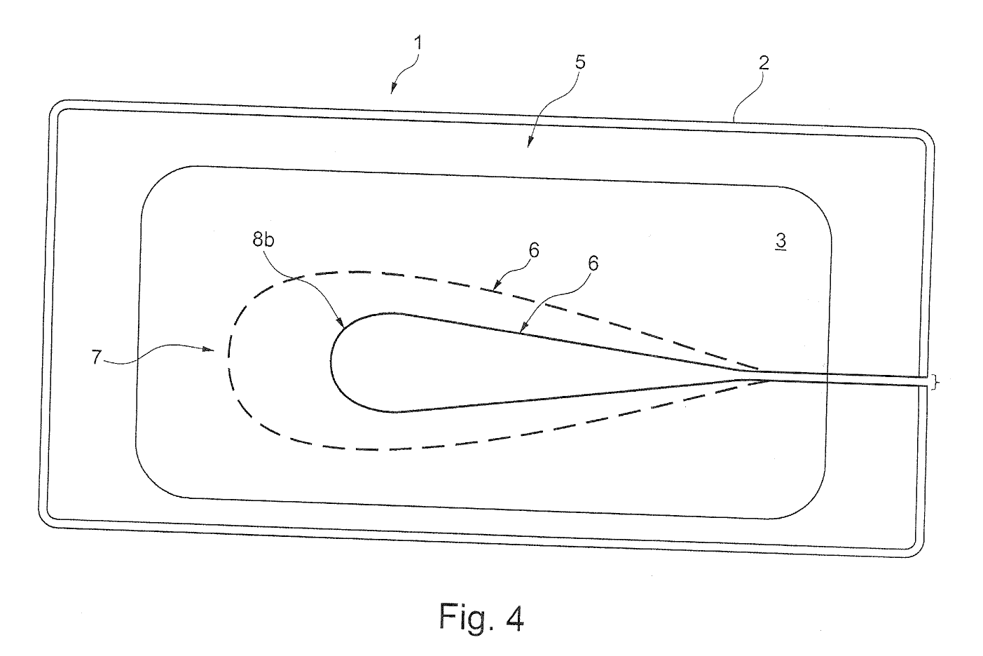

FIG. 4 shows a fourth exemplary embodiment of the apparatus 1 according to the invention, with the means 6 being in direct connection with the opening 4. The means 6 are located in the interior 5 of the housing 2. The means 6 are configured in such a way that an elastic bubble 8b is produced. The compensating volume 7 is thus formed within the elastic bubble 8b. In addition, the compensating volume can be formed to a greater or lesser extent within the elastic bubble 8b, depending on the pressure level. The elastic bubble 8b varies in a flexible manner, in terms of size and shape, depending on the prevailing conditions. The elastic bubble 8b is expediently also intended to prevent the ingress of dirt from the external environment through the opening 4. In a similar manner to FIG. 3, a filter device 9 and/or a moisture-absorbing element 10 can also be connected between the opening 4 and the elastic bubble 8b here.

The invention has been described with reference to preferred embodiments. However, it goes without saying for a person skilled in the art that structural changes and modifications can be implemented without leaving the scope of protection of the following claims.

### LIST OF REFERENCE SYMBOLS

1 Apparatus
2 Housing
3 Electrical Component
4 Opening
5 Interior of Housing
6 Means
7 Compensating Volume
8b Elastic Bubble
8m Elastic Membrane
9 Filter Device
10 Moisture-Absorbing Element
11 Cooling
12 External Environment
13 Housing Inner Wall
14 Pipeline System

1-7. (canceled)

8. An apparatus for adjusting environmental conditions, comprising:
a housing having an interior and an opening providing a connection to an external environment of the housing;
an electrical component, which conducts and/or stores current, surrounded by the housing; and
a means for protecting the electrical component from a flow of material and/or particles from the external environment, the means arranged in the interior of the housing and separating the electrical component from the opening.

9. The apparatus according to claim 8, wherein the means is flexible to allow for expansion and compensates for volume expansion.

10. The apparatus according to claim 9, wherein the means comprises an elastic membrane and/or an elastic bubble.

11. The apparatus according to claim 10, wherein the means comprises a filter device arranged at the opening.

12. The apparatus according to claim 11, wherein the means comprises a moisture-absorbing element and the moisture-absorbing element is arranged downstream of the filter device.

13. The apparatus according to claim 8, wherein the means comprises a moisture-absorbing element.

14. The apparatus according to claim 13, wherein the means comprises a filter device arranged at the opening with the moisture-absorbing element connected downstream of the filter device.

15. The apparatus according to claim 13, further comprising a cooling means for the electrical component, the cooling means arranged in the housing.

16. The apparatus according to claim 15, wherein the cooling means is a system of pipelines and/or is guided via the moisture-absorbing element.
